(19) United States
(12) Patent Application Publication
(10) Pub. No.: US 2012/0145240 A1
(43) Pub. Date: Jun. 14, 2012

(54) BARRIER FILMS FOR THIN-FILM PHOTOVOLTAIC CELLS

(75) Inventor: Peter Francis Carcia, Wilmington, DE (US)

(73) Assignee: E.I. DU PONT DE NEMOURS AND COMPANY, Wilmington, DE (US)

(21) Appl. No.: 13/391,880

(22) PCT Filed: Aug. 24, 2010
(86) PCT No.: PCT/US10/46457

§ 371 Date: Feb. 23, 2012

Related U.S. Application Data
(60) Provisional application No. 61/236,177, filed on Aug. 24, 2009.

(51) Int. Cl. H01L 31/0203; H01L 31/0376; H01L 31/0384; H01L 31/18

(52) U.S. Cl. 136/258; 438/64; 136/259; 257/E31.117

(57) ABSTRACT

A multilayer article having a cell substrate; a thin-film photovoltaic cell disposed on the cell substrate; an encapsulant layer disposed on the photovoltaic cell; and at least one plastic substrate coated on at least one side with one or more transparent, amorphous barrier layers disposed on the encapsulant layer. The invention extends to the process of making the article.

### CROSS-REFERENCE TO RELATED APPLICATION

The present application claims benefit of U.S. Provisional Patent Application Ser. No. 61/236,177, filed Aug. 24, 2009, which is incorporated herein in the entirety by reference thereto.

### FIELD OF THE INVENTION

A front sheet having a transparent, amorphous barrier layer made by an atomic layer deposition process. It is especially useful when applied to thin-film photovoltaic cells.

### BACKGROUND

The permeation of O₂ and H₂O vapor through polymer films is facile. To reduce permeability for packaging applications, polymers are coated with a thin inorganic film. Aluminum-coated polyester is common. Optically transparent barriers, predominantly SiOₓ or AlO_{y}, made either by physical vapor deposition (PVD) or chemical vapor deposition (CVD), are also used in packaging. The latter films are commercially available and are known in the industry as “glass-coated” barrier films. They provide an improvement for atmospheric gas permeation of about 10×, reducing transmission rates to about 1.0 cc O₂/m²/day and 1.0 ml H₂O/m²/day through polyester film (M. Izu, B. Dotter, and S. R. Ovshinsky, J. Photopolymer Science and Technology., vol. 8 1995 pp 195-204). While this modest improvement is a reasonable compromise between performance and cost for many high-volume packaging applications, this performance falls far short of packaging requirements in electronics. However, common CVD and PVD deposition methods entail initiation and film growth at discrete nucleation sites. The PVD method is particularly prone to creation of columnar microstructures having boundaries along which gas permeation can be facile. Electronic packaging usually requires at least an order of magnitude longer desired lifetime than, for example, beverage containers. As an example, flexible displays based on organic light emitting polymers (OLEDs) fabricated on flexible polyester substrates need an estimated barrier improvement of 10⁵-10⁶× for exclusion of atmospheric gases. Such gases can seriously degrade both the light-emitting polymer and the water-sensitive metal cathode, which can frequently be Ca or Ba. Thin-film photovoltaic cells projected to have long lifetimes (˜25 years) need a barrier improvement of 10⁴-10⁶×.

Because of their inherent free volume fraction, the intrinsic permeability of polymers is, in general, too high by a factor 10⁴-10⁶ to achieve the level of protection needed in electronic applications, such as flexible OLED displays or photovoltaic cells. Only inorganic materials, with essentially zero permeability, can provide adequate barrier protection. Ideally, a defect-free, continuous thin-film coating of an inorganic should be impermeable to atmospheric gases. However, the practical reality is that thin films have defects, such as pinholes, either from the coating process or from substrate imperfections which compromise barrier properties. Even grain boundaries in films can present a pathway for facile permeation. For the best barrier properties, films should be deposited in a clean environment on clean, defect-free substrates. The film structure should be amorphous. The deposition process should be non-directional, and the growth mechanism to achieve a featureless microstructure would ideally be layer-by-layer to avoid columnar growth with granular microstructure.

Atomic layer deposition (ALD) is a film growth method that satisfies many of these criteria for producing low permeation films. A description of the atomic layer deposition process can be found in “Atomic Layer Epitaxy,” by Tuomo Suntola in Thin Solid Films, vol. 216 (1992) pp. 84-89. As its name implies, films grown by ALD form by a layer-by-layer process. ALD is in contrast to growth by common CVD and PVD methods where growth is initiated and proceeds at finite numbers of nucleation sites on the substrate surface. The latter technique can lead to columnar microstructures with boundaries between columns along which gas permeation can be facile. ALD can produce very thin films with extremely low gas permeability, making such films attractive as barrier layers for packaging sensitive electronic devices and components built on plastic substrates.

Photovoltaic (PV) cells that convert solar radiation or light into electricity need to operate year round in harsh outdoor conditions. To insure longevity of 25 years or more, solar cells need robust packaging. For integrating solar cells into building materials such as a roof-top membrane, it is also desirable that PV cells be a flexible product in roll form.

Thin-film PV cells can be fabricated as a roll product on metal foil or flexible substrates. The top or front sheet for flexible PV cells that principally collects solar radiation should be optically transparent, weather-resistant, and soil-resistant, with low permeability for moisture and other atmospheric gases. When the PV cell is fabricated on a partially transparent cell substrate, a transparent backsheet with a moisture barrier also can improve cell performance by collecting reflected light, while the barrier simultaneously protects the PV cell from moisture ingress.

Thin-film PV cells are based on amorphous silicon (a-Si), cadmium telluride (CdTe), copper indium (gallium) di-selenide/sulfide (CIS/CIGS), and dye-sensitized, organic and nano-materials. Moisture sensitivity is an issue for all thin-film technologies, and is particularly acute in CIGS cells. To achieve a 25-year lifetime, a CIGS cell needs a barrier with a water vapor transmission rate <5×10⁻⁴ g-H₂O/m²day. Nonetheless, CIGS PV cells are attractive because of their high efficiency (˜20% for small laboratory-size cells).

A typical packaging scheme for thin-film cells uses glass as the front and back sheets. This rigid structure can be impermeable with long lifetime. Alternatively the structure can be flexible, consisting of a metal foil or polymer substrate, on which the PV cell is fabricated, an encapsulant material, and a flexible transparent frontsheet, typically a polymer. However, without including a moisture barrier, the thin film cells with a flexible, transparent, polymer front sheet will have a limited lifetime.

There remains a need for flexible front sheet structures that meet the packaging needs for thin-film PV cells, especially CIGS cells.

### SUMMARY OF THE INVENTION

The invention describes a multilayer article comprising:
(a) a cell substrate;
(b) a thin-film photovoltaic cell disposed on the cell substrate wherein the photovoltaic cell is selected from the group consisting of nanocrystalline Si, amorphous silicon (a-Si), cadmium telluride (CdTe), copper indium (gallium) di-selenide/sulfide (CIS/CIGS), dye-sensitized, and organic materials;
(c) an encapsulant layer disposed on the thin-film photovoltaic cell; and
(d) at least one plastic substrate disposed on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof. and wherein the plastic substrate is coated by a process of atomic layer deposition.

The invention further describes a process for making a multilayer article comprising:
(a) providing a cell substrate;
(b) disposing a thin-film photovoltaic cell on the cell substrate;
(c) disposing an encapsulant layer on the thin-film photovoltaic cell, the cell being based on a material selected from the group consisting of nanocrystalline Si, amorphous silicon (a-Si), cadmium telluride (CdTe), copper indium (gallium) di-selenide/sulfide (CIS/CIGS), dye-sensitized, and organic materials;
   (d) disposing at least one plastic substrate on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof and formed by a process of atomic layer deposition.

The atomic layer deposition process employed in the foregoing process may comprise:
(a) placing the plastic substrate and thin-film photovoltaic cell disposed thereon in a reaction chamber held at a temperature from 50° C. to 250° C.;
(b) admitting a first precursor vapor into the chamber to form an adsorbed precursor layer on the plastic substrate;
(c) purging the vapor from the reaction chamber;
(d) admitting a second precursor into the reaction chamber, wherein said second precursor reacts with the adsorbed precursor material to form a transparent, amorphous barrier layer;
(e) purging the reaction chamber of volatile reactants and reaction products produced by the reaction; and
(f) repeating the steps (b), (c), (d), and (e) for a number of times sufficient to form the one or more transparent, amorphous barrier layers having a preselected thickness.

### BRIEF DESCRIPTION OF THE FIGURES

The invention will be more fully understood and further advantages will become apparent when reference is had to the following detailed description of the preferred embodiments of the invention and the accompanying drawings, wherein like reference numeral denote similar elements throughout the several views and in which:

FIG. 1 illustrates a test cell configuration for Example 1;

FIG. 2 illustrates a graph of optical data for Example 1;

FIG. 3 illustrates a test cell configuration for Example 2;

FIG. 4 illustrates a graph of optical data for Example 2;

FIG. 5 illustrates a test cell configuration for Example 3;

FIG. 6 illustrates a graph of optical data for Example 3; and

FIG. 7 illustrates a test cell configuration for Example 4.

### DETAILED DESCRIPTION

Atomic layer deposition (ALD) is a film growth method wherein a vapor of film precursor is adsorbed on a substrate in a reaction chamber. The vapor is then purged from the chamber, leaving an adsorbed layer of precursor, which may be a monolayer, on the substrate. The purging can be carried out by evacuation or by flowing inert gas through the chamber, or any combination thereof. As used herein, the term “adsorbed layer” is understood to mean a layer whose atoms are bound to the surface of a substrate. A second precursor is then introduced into the chamber under thermal conditions, which promote reaction with the adsorbed layer of precursor forming a layer of the desired material. The reaction products are pumped from the chamber. Subsequent layers of material can be formed by again exposing the substrate to the precursor vapor and repeating the deposition process for a number of times sufficient to form a layer having a preselected thickness. Transparent, amorphous barrier layers are formed as described above.

Described herein are transparent, amorphous barrier layers formed by ALD on plastic substrates and useful for preventing the passage of atmospheric gases. The substrates with barrier layer(s) are used as front sheets or back sheets in photovoltaic cells.

In one embodiment, a multilayer article is described having:
a) a cell substrate;
b) a thin-film photovoltaic cell disposed on the cell substrate and based on a material selected from the group consisting of nanocrystalline Si, amorphous silicon (a-Si), cadmium telluride (CdTe), copper indium (gallium) di-selenide/sulfide (CIS/CIGS), dye-sensitized, and organic materials;
c) an encapsulant layer disposed on the thin-film photovoltaic cell; and
d) at least one plastic substrate disposed on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof and formed by a process of atomic layer deposition.

The plastic substrates of this invention are optically transparent and flexible, and include a general class of polymeric materials, such as those described in Polymer Materials, (Wiley, New York, 1989) by Christopher Hall or Polymer Permeability, (Elsevier, London, 1985) by J. Comyn. Common examples include polyethylene terephthalate (PET), poly(propylene terephthalate (PTT) and polyethylene naphthalate (PEN), which are commercially available by the roll as film base. For application as a back sheet for photovoltaic devices, the plastic substrate can be optically transparent as described above, but, also, may include non-transparent flexible substrates, such as translucent substrates (e.g., polyimides). The plastic substrates may include concentrations of chemical additives, that absorb uv radiation and/or reduce water absorption. Additives could improve durability of the polymer substrate in an application as a front or back sheet in a photovoltaic device.

The materials formed by ALD, suitable for barrier layers, include oxides and nitrides of Groups IVB, VB, VIB, IIIA, and IVA of the Periodic Table and combinations thereof. Of particular interest in this group are SiO₂, Al₂O₃, TiO₂, ZrO₂, HfO₂, and Si₃N₄. One advantage of the oxides in this group is optical transparency, which is attractive for electronic displays and photovoltaic cells where visible light must either exit or enter the device. The nitrides of Si and Al are also transparent in the visible spectrum. It is to be understood that the term “visible light” as used herein includes electromagnetic radiation having a wavelength that falls in the infrared and ultraviolet spectral regions, as well as wavelengths generally perceptible to the human eye, all being within the operational limits of typical optoelectronic devices.

The precursors used in the ALD process to form these barrier materials can be selected from precursors tabulated in published references such as M. Leskela and M. Ritala, “ALD precursor chemistry: Evolution and future challenges,” in Journal de Physique IV, vol. 9, pp 837-852 (1999) and references therein. The preferred range of substrate temperature for synthesizing these barrier coatings by ALD is 50° C.-250° C. Too high temperature (>250° C.) is incompatible with processing of temperature-sensitive plastic substrates, either because of chemical degradation of the plastic substrate or disruption of the ALD coating because of large dimensional changes of the substrate. The reaction kinetics generally are found to be too slow below 50° C.

In a representative implementation, the ALD process can employ trimethyl aluminum and water, whose overall reaction can be specified as:

2 Al(CH₃)₃+3 H₂O→Al₂O₃+6 CH₄.

In the actual process, the reaction proceeds in two half-reactions at the surface that may be represented as:

Al—(CH₃)*+H₂O→Al—OH*+CH₄

Al—OH*+Al(CH₃)₃→Al—O—Al(CH₃)₂+CH₄,

with “*” indicating a species present at the surface of the material being coated. Of course, the ALD process may be carried out with other precursors and reactants.

In an embodiment, a process is described for making a multilayer article by:
a. providing a cell substrate;
b. disposing a thin-film photovoltaic cell on the cell substrate;
c. disposing an encapsulant layer on the thin-film photovoltaic cell, the cell being based on a material selected from the group consisting of nanocrystalline Si, amorphous silicon (a-Si), cadmium telluride (CdTe), copper indium (gallium) di-selenide/sulfide (CIS/CIGS), dye-sensitized, and organic materials;
d. disposing at least one plastic substrate on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof and formed by a process of atomic layer deposition.

In an embodiment, the atomic layer deposition process employed may comprise:
a. placing the plastic substrate and thin-film photovoltaic cell disposed thereon in a reaction chamber held at a temperature from 50° C. to 250° C.;
b. admitting a first precursor vapor into the chamber to form an adsorbed precursor layer on the plastic substrate;
c. purging the vapor from the reaction chamber;
d. admitting a second precursor into the reaction chamber, wherein said second precursor reacts with the adsorbed precursor material to form a transparent, amorphous barrier layer;
e. purging the reaction chamber of volatile reactants and reaction products produced by the reaction; and
f. repeating the steps (b), (c), (d), and (e) for a number of times sufficient to form the one or more transparent, amorphous barrier layers having a preselected thickness.

A thickness range found to be suitable for barrier films on the plastic substrate is 2 nm-100 nm. A more preferred range is 2-50 nm. Thinner layers will be more tolerant to flexing without cracking. This is extremely important for polymer substrates where flexibility is a desired property. Film cracking will compromise barrier properties. Thin barrier films also increase transparency in the cases of electronic devices where input or output of light is important. There may be a minimum thickness corresponding to continuous film coverage, for which substantially all of the imperfections of the substrate are covered by the barrier film. For a nearly defect-free substrate, the threshold thickness for acceptable barrier properties was estimated to be at least 2 nm, but may be as thick as 35 nm and all thicknesses found within this range are included herein. It has been found that a 25 nm thick ALD barrier layer is typically sufficient to reduce oxygen transport through a polymer film to a level below a measurement sensitivity of 0.0005 g-H₂O/m²/day.

Some plastic substrates coated by ALD may require a “starting layer,” also known as a “nucleation layer,” to promote continuous ALD film growth on the plastic substrate or the article requiring protection. The preferred thickness of the nucleation layer is in the range of 1 nm-100 nm. Materials for the nucleation layer will generally be selected from the same group of materials to be used for the barrier layer(s). Aluminum oxide, silicon oxide, and silicon nitride are preferred for the nucleation layer, which may also be deposited by ALD, although other methods such as chemical and physical vapor deposition methods may also be suitable. Surface treatment of the plastic surface can also be used to promote nucleation of the ALD barrier layer on plastic and reduce the ALD threshold thickness for good barrier properties. Suitable surface treatments include chemical, physical, and plasma methods.

In one embodiment, the basic building block of a plastic substrate with barrier layer is a barrier layer coated by ALD on one side of a plastic substrate, where the substrate has an optional nucleation layer and/or has optionally been surface treated. In one embodiment, the basic building block is a barrier layer coated by ALD on each side of a plastic substrate, where the substrate has an optional nucleation layer and/or has optionally been surface treated. These basic building blocks can then be combined in any number of combinations by lamination to form multiple, independent barrier layers.

The plastic substrate coated with at least one barrier layer described above is particularly useful for a front sheet for copper indium gallium (di)selenide (CIGS) photovoltaic cells and other thin-film photovoltaic cells that are found in the photovoltaic commercial market, such as nanocrystalline Si, amorphous silicon (a-Si), cadmium telluride (CdTe), dye-sensitized, and organic materials. The photovoltaic cell to receive a front sheet with an ALD barrier coating(s) can be of any of several configurations and comprises a cell substrate, a metal layer for back contact, one or more absorber layers, a window layer, a transparent conducting oxide TCO layer, and a metal grid top contact layer. Some embodiments also contain one or more layers selected from window layers, buffer layers, and interconnect layers.

In general, the cell substrate on which the photovoltaic cell is fabricated is made from metal, polymer, or glass. Metal and polymer substrates have the advantage of being flexible; glass and some polymers have the advantage of being transparent or translucent. Suitable polymers include, but are not limited to polyesters (e.g., PET, PEN), polyamides, polyacrylates and polyimides.

The TCO layer typically comprises mixtures or doped oxides of In₂O₃, SnO₂, ZnO, CdO, and Ga₂O₃. Common examples in PV cells include ITO (In₂O₃ doped with about 9 atomic % Sn) and AZO (ZnO doped with 3-5 atomic % Al).

The absorber layer absorbs light from the solar spectrum (400-1200 nm). Suitable absorber materials include ternary chalchopyrite compounds such as CuInSe₂, CuInS₂, CuGaSe₂, CuInS₂, CuGaS₂, CuAlSe₂, CuAlS₂, CuAlTe₂, CuGaTe₂ and combinations thereof, and CdTe and related compounds.

The window layer is a thin semiconductor film (an n-type if the absorber is a p-type, or a p-type if the absorber is an n-type) that forms a heterojunction with the absorber layer, by which electric charges are separated by the built-in electric field at the junction. In this description, n-type refers to semiconductors in which electrical conduction is predominately by electron carriers, and p-type refers to semiconductors wherein electrical conduction is predominately by hole carriers. Suitable materials for the window layer include CdS, ZnS, ZnSe, In₂S₃, (Zn,Cd)S, and Zn(O,S) for a chalcopyrite absorber, and ITO, CdS and ZnO for a CdTe absorber.

The layer for back-contact is typically either a TCO layer or a metal.

The buffer layer is typically a transparent, electrically insulating dielectric. Suitable materials include ZnO, Ga₂O₃, SnO₂, and Zn₂SnO₄.

The front sheet with the barrier layer(s) can also be used to protect amorphous or nanocrystalline thin-film silicon (a-Si, nc-Si) solar cells. The structure of a-Si and nc-Si solar cells is commonly p-i-n for a single cell, wherein “n” refers to n-type Si, “i” refers to insulating Si, and “p” refers to p-type Si. Tandem cells with higher efficiency are produced by stacking this basic cell and optimizing the absorption of the stack.

Thin-film silicon solar cells typically comprise a TCO layer, a p-type Si alloy layer, an i-Si alloy layer, an n-type Si alloy layer, a buffer layer, a metal layer and a substrate.

Amorphous or nanocrystalline Si is usually an alloy with hydrogen, i.e., a-Si:H or nc-Si:H. Doping n-type or p-type can be accomplished using common dopants used for crystalline Si. Suitable p-type dopants include Group III elements (e.g., B). Suitable n-type dopants include Group V elements (e.g., P). Alloying with Ge or C can also be used to change the optical absorption characteristics and other electrical parameters.

### EXAMPLES

### Example 1

Referring to FIG. 1, there is depicted generally at 10 a test cell configuration used to characterize the permeation of the present ALD layers. Front sheet 12, a 0.002 inch (2 mil) thick fluoropolymer (DuPont Teflon® FEP 200C sold by E. I. du Pont de Nemours and Company, Wilmington, Del.) weatherproof layer, was coated on one side at room temperature with a 1 mil thick contact adhesive 14 (Polatechno, AD-20 sold by Polatechno Co., Ltd., Tokyo, Japan). A 7-mil thick PET substrate 18 (DuPont Teijin Films ST504 sold by Dupont Teijin Films US Limited Partnership, Chester, Va.) was coated at 100° C. by atomic layer deposition with about a 25 nm thick Al₂O₃ barrier layer 16. Then the adhesive coated side of the FEP layer 12 was laminated to the Al₂O₃ barrier layer side of the PET substrate 18, resulting in a flexible front sheet.

The Al₂O₃ barrier layer 16 was prepared by atomic layer deposition. The precursors used were trimethyl aluminum (TMA) vapor and water vapor. The precursors were introduced sequentially into a reactor (Cambridge Nanotech Savannah 200 made by Cambridge Nano Tech, Cambridge, Mass.). The reactor was continuously purged with nitrogen gas at 20 sccm and pumped with a small mechanical pump to a background pressure (no reactant or precursor) of about 0.3 Torr. The nitrogen gas was used as a carrier for the TMA and H₂O precursors, and also as a purging gas. More specifically, the PET substrate was dosed with water vapor carried by nitrogen gas for 15 milliseconds, followed by purging of the reactor with flowing nitrogen for 30 seconds. The substrate was then dosed for 15 milliseconds with trimethyl aluminum vapor carried by nitrogen gas, followed by a 15 second purge of flowing nitrogen. This reaction sequence produced a layer of Al₂O₃ on the substrate. The reaction sequence was repeated 250 times, which formed an Al₂O₃ barrier layer approximately 25 nm thick on the PET substrate. Because of the high diffusivity of precursors in atomic layer deposition, a portion of the surface of the PET facing the bottom of the reactor was also coated with a layer of Al₂O₃. The portion of the surface facing the bottom appeared to be coated with the layer of Al₂O₃ near the edges of the PET substrate.

To test the barrier properties of the flexible front sheet, a uv-curable epoxy 20 (˜0.150 mm thick, ELC-2500, sold by Electro-Lite Corp, Danbury, Conn.) used as an encapsulant layer was coated onto the exposed PET substrate side of the front sheet. The epoxy coated side was then laminated to a side of a glass substrate 24 having discrete squares of a thin (˜60 nm thick) semi-transparent Ca layer 22. The squares were defined and formed by evaporation through a shadow mask. The deposition of the Ca layer 22 and the lamination were done in a nitrogen atmosphere because of the extreme air-sensitivity of Ca. The Ca was used in place of a thin-film PV cell in the test for barrier properties, because Ca is even more moisture sensitive than a typical thin-film PV cell. It, therefore, allows more rapid evaluation of the effectiveness of the flexible front sheet regarding the exclusion of water vapor ingress and mechanical integrity.

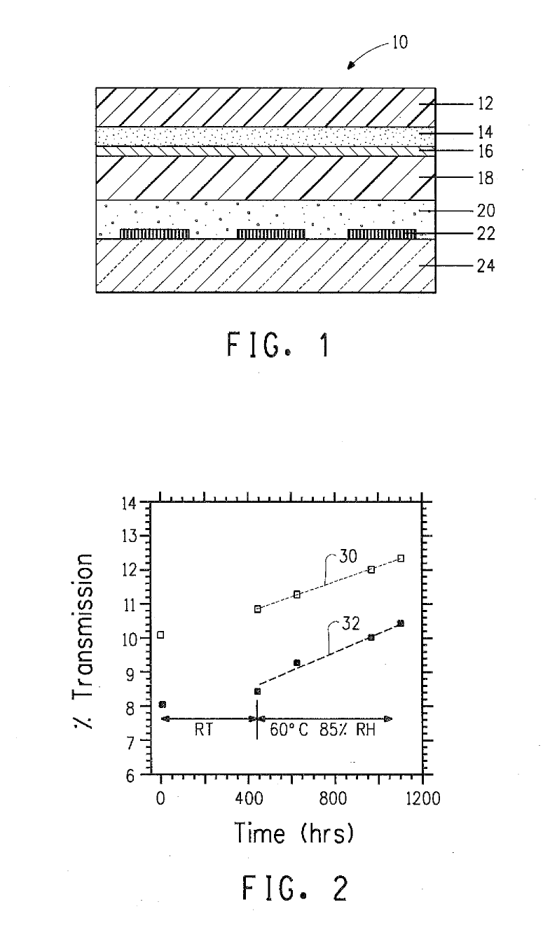

FIG. 2 provides data showing the effectiveness of the ALD barrier of the FIG. 1 structure in inhibiting water permeation. The data and fitted line 30 of FIG. 2 plot the change in optical transmission through the front sheet side of the Ca-coated test cell of FIG. 1, as a function of exposure, first to ambient laboratory conditions and then to an atmosphere at 60° C. and 85% RH. The increase in optical transmission after this exposure is believed to result from conversion of some of the Ca metal to Ca(OH)₂ by reaction with permeating water vapor.

The same experiment was also carried out on a control cell having the same structure, except that the ALD-coated front sheet was replaced by a glass front sheet. The resulting data are shown as trace 32.

The optical data shown in FIG. 2 indicate that the flexible front sheet structure ages more slowly than the control for accelerated aging of more than 1000 hrs at 60° C. and 85% relative humidity. The WVTR (water vapor transmission rate) calculated from the data was less than 5×10⁻⁴ g-H₂O/m²-day, the approximate limit of the Ca-test cell at 60° C. and 85% RH. and is attributable to edge permeation through the epoxy seal, for both the control cell and the flexible front sheet structure.

### Example 2

The structure discussed in this example is illustrated in FIG. 3. A 25 nm thick Al₂O₃ barrier layer 40a, 40b was deposited at 120° C. by atomic layer deposition on both sides of a 5 mil thick PEN (DuPont Teijin Films Kaladex® polyethylene naphthalate, 2-mil thick) substrate 42 by elevating the PEN slightly above the bottom of a reactor. The Al₂O₃ barrier layers were deposited by atomic layer deposition using trimethyl aluminum and water vapor as the reactants. The precursor vapors were introduced sequentially into the reactor (Cambridge Nanotech Savannah 200), which was continuously purged with nitrogen gas at 20 sccm and pumped with a small mechanical pump to a background pressure (no reactant or precursor present) of about 0.3 Torr. In a single reaction cycle, the heated PEN substrate 42 was dosed with water vapor for 15 milliseconds, followed by purging of the reactor in flowing nitrogen for 30 seconds, then dosed for 15 milliseconds with trimethyl aluminum, followed by a 15 second purge in flowing nitrogen. This reaction sequence produced essentially a monolayer of Al₂O₃. The reaction sequence was repeated 250 times, which formed an Al₂O₃ layer approximately 25 nm thick on the PEN substrate. Because of the high diffusivity of precursors in atomic layer deposition, the surface of the PEN facing the bottom of the reactor was also coated with a layer of Al₂O₃. A 2 mil thick Teflon® FEP fluoropolymer (DuPont FEP 200C) weatherproof top sheet 12 having a 1 mil contact adhesive 14 (Polatechno, AD-20) deposited on one side was laminated to the Al₂O₃ deposited PEN substrate 42 forming a laminated structure. The Al₂O₃ deposited PEN substrate side of this laminated structure was then attached by using a uv-curable epoxy 20 to a Ca-test cell that included a glass substrate 24 having a thin (˜60 nm thick) semi-transparent Ca layer 22, as described in Example 1.

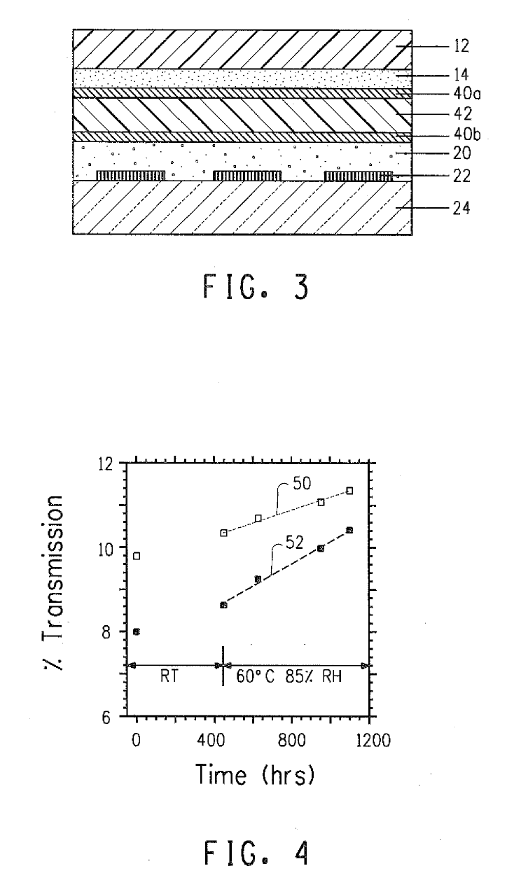

Data indicative of the permeation of water vapor were collected using the same optical transmission technique employed for Example 1. As shown in FIG. 4, trace 50 is a plot of the change in optical transmission through the front sheet side of the Ca-coated test cell with the flexible front sheet structure, versus time of storage at 60° C. and 85% relative humidity. For comparison, a control cell having the same structure, but with the Al₂O₃-coated PEN layer 42 replaced by a glass front sheet was made. Trace 52 indicates the performance of the control cell under the same exposure conditions. The increase in optical transmission for both was postulated to occur because of conversion of some of the Ca metal to Ca(OH)₂ by reaction with permeating water vapor. The optical data shown in FIG. 4 indicates that the flexible front sheet structure ages more slowly than the glass control for accelerated aging more than 1000 hrs at 60° C. and 85% relative humidity. The WVTR (water vapor transmission rate) calculated from the data was less than 5×10⁻⁴ g-H₂O/m²-day, the approximate limit of this Ca-test at 60° C. and 85% RH, attributed to edge permeation through the epoxy seal, for both the glass control cell and the flexible front sheet structure.

### Example 3

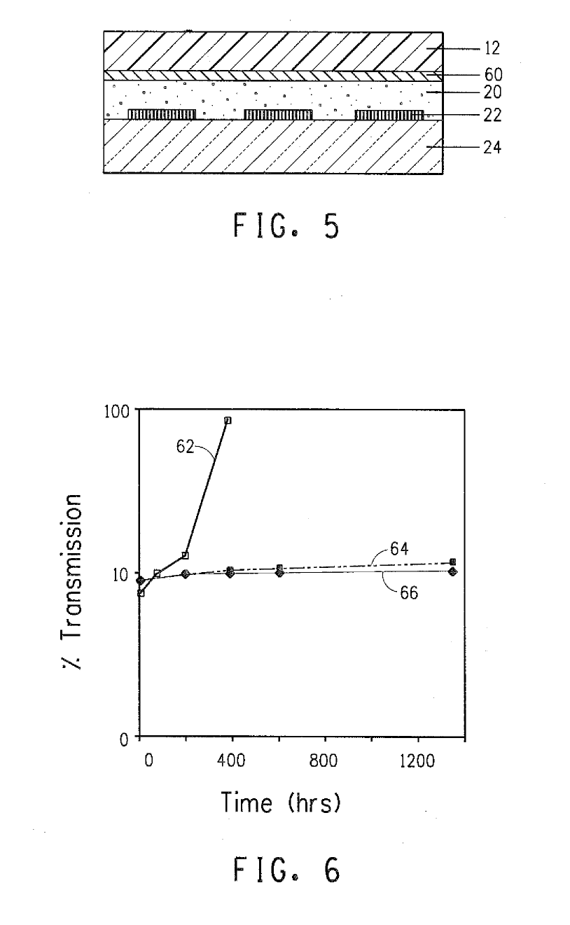

FIG. 5 depicts yet another test structure in which an ALD barrier layer is disposed directly on a weatherproof front sheet. Al₂O₃ barrier layer 60 was deposited by atomic layer deposition directly on a Teflon® fluoropolymer (DuPont FEP 200C) weatherproof layer 12. The Al₂O₃ barrier film was deposited by atomic layer deposition on 2 mil thick FEP at 50° C. by using trimethyl aluminum and water precursors. The precursor vapors were introduced sequentially into the reactor (Cambridge Nanotech Savannah 200), which was continuously purged with nitrogen gas at 20 sccm and pumped with a small mechanical pump to a background pressure (no reactants present) of about 0.3 Torr. The nitrogen gas was used as a carrier for the precursors and, also, as a purging gas. A single reaction cycle produces essentially a monolayer of Al₂O₃. In a single reaction cycle, the heated FEP substrate was dosed with water vapor for 15 milliseconds, followed by purging of the reactor in flowing nitrogen for 100 seconds, then dosed for 15 milliseconds with trimethyl aluminum, followed by a 50 second purge in flowing nitrogen. This reaction sequence produced essentially a monolayer of Al₂O₃. The reaction sequence was repeated 250 times, which formed a transparent amorphous Al₂O₃ layer approximately 25 nm thick on the FEP substrate.

To test the barrier properties of the flexible front sheet, a uv-curable epoxy 20 (˜0.150 mm thick, ELC-2500, Electro-Lite Corp, Danbury, Conn.) was coated onto the Al₂O₃ side of the FEP coated front sheet. The epoxy coated side was then laminated to a glass substrate 24 forming a flexible front sheet structure. The laminated side of the glass substrate had a thin (˜60 nm thick) semi-transparent Ca layer 22 deposited thereon. The deposition of the Ca layer and the lamination were done in a nitrogen atmosphere because of the extreme air-sensitivity of Ca. The Ca was used in place of a thin-film PV cell in the following test for barrier properties, because Ca is more moisture sensitive than a typical thin-film PV cell. It allows for more rapid evaluation of the effectiveness of the flexible front sheet regarding the exclusion of water vapor ingress and mechanical integrity.

The same optical transmission technique employed for Examples 1 and 2 was repeated with the FIG. 5 structure. As shown in FIG. 6, trace 64 is a plot of the change in optical transmission through the front sheet side of the Ca-coated glass test cell with flexible front sheet structure versus time of storage at 24° C. and ˜50% relative humidity. A glass front sheet control cell was made with the same configuration as that of the FIG. 5 cell, but with a glass front sheet replacing the flexible front sheet. This control cell produced the data indicated by trace 66. The increase in optical transmission with aging at 24° C. and ˜50% RH was postulated to occur because of conversion of some of the Ca metal to Ca(OH)₂ by reaction with permeating water vapor. The optical data indicates that the flexible front sheet structure ages in a similar manner as the control for more than 1000 hrs at 24° C. and ˜50% relative humidity. The WVTR (water vapor transmission rate) calculated from the data was 1×10⁻⁴ g-H₂O/m²-day. The behavior of the coated FEP sheet was also compared to that of an uncoated FEP sheet, which showed a very rapid increase 62 in transmission, which is believed to indicate substantial permeation of water through the unprotected sheet.

### Example 4

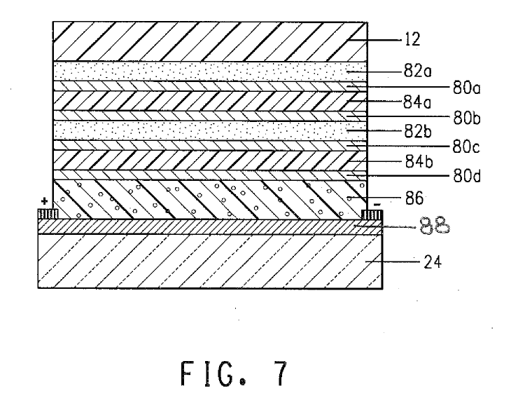

The benefit of improved resistance to gas permeation provided by ALD barrier layers, as demonstrated by Examples 1-3 above, was confirmed by testing of an actual thin-film photovoltaic cell device, as illustrated in FIG. 7. The cell device included a front sheet 12 made with a 0.002 inch (2 mil) thick fluoropolymer (DuPont Teflon® FEP 200C) weatherproof layer, which was coated on one side at room temperature with a 1 mil thick contact adhesive 82a (Polatechno, AD-20). Two 5-mil thick PEN (polyethylene naphthalate) substrates 84a, 84b (Q65 A, heat-stabilized PEN, sold by DuPont Teijin Films) were each coated on both sides by atomic layer deposition (ALD). The ALD process was carried out with the substrates held at 120° C., producing about a 25 nm thick Al2O3 barrier layer on each side, resulting in coatings 80a and 80b on substrate 84a and coatings 80c and 80d on substrate 84b. The two ALD coated PEN substrates 84a, 84b were laminated together with a 1 mil contact adhesive 82b. Then the adhesive-coated side of the FEP layer was laminated to one of the sides of the laminated PEN sheet, resulting in a flexible front sheet.

The Al2O3 barrier films 80a-d were prepared by the process of atomic layer deposition. The precursors used were trimethyl aluminum vapor and water vapor. The precursors were introduced sequentially into a reactor (Cambridge Nanotech Savannah 200). The reactor was continuously purged with a nitrogen gas at 20 sccm and pumped with a small mechanical pump to a background pressure (no reactant or precursor) of about 0.3 Torr. The nitrogen gas was used as a carrier for the reactants and also, as a purging gas. More specifically, the PEN substrate was dosed with water vapor carried by nitrogen gas for 15 milliseconds, followed by purging of the reactor with flowing nitrogen for 30 seconds. The substrate was then dosed for 15 milliseconds with trimethyl aluminum vapor carried by nitrogen gas, followed by a 15 second purge of flowing nitrogen. This reaction sequence produced a layer of Al2O3 on the substrate. The reaction sequence was repeated 250 times, which formed an Al2O3 barrier layer approximately 25 nm thick on the PEN substrate. Because of the high diffusivity of precursors in atomic layer deposition, the surface of the PEN in contact with the bottom of the reactor was also coated with a layer Al2O3. Coating both sides can further reduce the gas permeation compared to one barrier layer. A further advantage is that adhesion to an encapsulant or other layer is improved with an oxide coated surface.

To test the barrier properties of the flexible front sheet, a thermoplastic encapsulant 86, which was 0.018″ (18 mils) thick, was used to bond the flexible front sheet to a thin-film photovoltaic cell 88 with a Cu(In, Ga)Se₂ (CIGS) absorber. This CIGS PV cell 88 with barrier front sheet was aged for 43 days at 85° C. and 85% relative humidity, while simultaneously exposing the PV cell to constant illumination at 1000 W/m² from a solar simulator. Photovoltaic properties were measured before and after the 43 days of aging to assess the effectiveness of the barrier front sheet.

The photovoltaic (PV) cell 88 was fabricated on a 2 inch×2 inch glass substrate using a structure and methods well known in the art of CIGS cell fabrication. The layers consisted of a Mo metal layer on glass; an absorber layer of Cu(In, Ga) Se2, a thin window layer of CdS, a thin insulating buffer layer of ZnO, a transparent conducting oxide which was indium-tin oxide (ITO), and a metal grid electrode of a Ni/Al alloy with a Ni/Al tab electrode. The cell size of 1 cm² was defined by the ITO layer, which was deposited through a shadow mask, 1 cm×1 cm. To improve adhesion to the encapsulant, the entire surface of the CIGS PV cell was coated with a thin (25 nm) insulating and passivating layer of ZnO. Electrical contact to the bottom Mo layer and the top Ni/Al tab electrode was made through vias that penetrated the ZnO passivation layer. The front sheet barrier, thermoplastic encapsulant, and the CIGS PV cell were laminated together by applying pressure to the stack at 150° C. for 10 minutes in a pressure laminator.

Before aging, this PV cell had an open circuit voltage (V_{oc}) equal to 0.566 V. After aging for 43 days at 85° C. and 85% relative humidity with simultaneous solar illumination, the open circuit voltage was 0.547 V, a reduction of only about 3%, which demonstrates the effectiveness of the front sheet with ALD barrier to exclude moisture which can damage the CIGS photovoltaic cell. It is notable that the CIGS cell, which is known to be highly moisture sensitive, performed well, notwithstanding the use of water vapor as a reactant in the ALD process.

What is claimed is:

1. A multilayer article comprising:
(a) a cell substrate;
(b) a thin-film photovoltaic cell disposed on the cell substrate wherein the photovoltaic cell being based on a material selected from the group consisting of nanocrystalline Si, amorphous silicon (a-Si), cadmium telluride (CdTe), copper indium (gallium) di-selenide/sulfide (CIS/CIGS), dye-sensitized, and organic materials;
(c) an encapsulant layer disposed on the thin-film photovoltaic cell; and
(d) at least one plastic substrate disposed on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof, and wherein the plastic substrate is coated on at least one side with one or more transparent, amorphous barrier layers by a process of atomic layer deposition.

2. The multilayer article of claim 1 wherein the transparent, amorphous barrier layer is selected from the group consisting of SiO₂, Al₂O₃, TiO₂, ZrO₂, HfO₂, Si₃N₄ and combinations thereof.

3. The multilayer article of claim 1 wherein the transparent, amorphous barrier layer is Al₂O₃, and the atomic layer deposition process is carried out using trimethyl aluminum and water vapor reactants.

4. The multilayer article of claim 1 further comprising an adhesive layer disposed on the at least one plastic substrate.

5. The multilayer article of claim 1 further comprising an adhesive layer disposed between the coated side of the plastic substrate and a weatherproof layer.

6. The multilayer article of claim 1 further comprising a nucleation layer interposed between the plastic substrate and the transparent, amorphous barrier layer.

7. The multilayer article of claim 1 wherein the transparent, amorphous barrier layer has a thickness ranging from 2 nm to 100 nm.

8. The multilayer article of claim 1 wherein the transparent, amorphous barrier layer has a thickness ranging from 2 nm to 50 nm.

9. A process for making a multilayer article comprising:
(a) providing a cell substrate;
(b) disposing a thin-film photovoltaic cell on the cell substrate, the cell being based on a material selected from the group consisting of nanocrystalline Si, amorphous silicon (a-Si), cadmium telluride (CdTe), copper indium (gallium) di-selenide/sulfide (CIS/CIGS), dye-sensitized, and organic materials;
(c) disposing an encapsulant layer on the thin-film photovoltaic cell; and
(d) disposing at least one plastic substrate on the encapsulant layer, wherein the plastic substrate is coated on at least one side with one or more transparent, amorphous barrier layers selected from the group consisting of oxides and nitrides of Groups IVB, VB, VIB, IIIA, and IVA of the Periodic Table and combinations thereof and formed by a process of atomic layer deposition.

10. The process of claim 9 wherein the process of atomic layer deposition comprises:
(a) placing the plastic substrate and thin-film photovoltaic cell disposed thereon in a reaction chamber held at a temperature from 50° C. to 250° C.;
(b) admitting a first precursor vapor into the chamber to form an adsorbed precursor layer on the plastic substrate;
(c) purging the vapor from the reaction chamber;
(d) admitting a second precursor into the reaction chamber, wherein said second precursor reacts with the adsorbed precursor material to form a transparent, amorphous barrier layer;
(e) purging the reaction chamber of volatile reactants and reaction products produced by the reaction; and
(f) repeating the steps (b), (c), (d), and (e) for a number of times sufficient to form the one or more transparent, amorphous barrier layers having a preselected thickness.

11. The process of claim 10 wherein the transparent, amorphous barrier layer is selected from the group consisting of SiO₂, Al₂O₃, TiO₂, ZrO₂, HfO₂, Si₃N₄ and combinations thereof.

12. The process of claim 11 wherein the transparent, amorphous barrier layer is Al₂O₃, and the atomic layer deposition process is carried out using trimethyl aluminum and water vapor reactants.

13. The process of claim 10, further comprising forming a nucleation layer on the plastic substrate prior to deposition thereon of the one or more transparent, amorphous barrier layers.

14. The process of claim 10 wherein the preselected thickness ranges from 2 nm to 100 nm.

15. The process of claim 10 wherein the preselected thickness ranges from 2 nm to 50 nm.
